(19) United States
(12) Patent Application Publication
(10) Pub. No.: US 2025/0373036 A1
(43) Pub. Date: Dec. 4, 2025

(54) CHARGER

(71) Applicant: LG ELECTRONICS INC., Seoul (KR)

(72) Inventors: Bumseok SHON, Seoul (KR); Junghyun LEE, Seoul (KR); Myoungku LEE, Seoul (KR); Jungyoun RUE, Seoul (KR); Minjung KIM, Seoul (KR)

(73) Assignee: LG ELECTRONICS INC., Seoul (KR)

(21) Appl. No.: 18/762,036

(22) Filed: Jul. 2, 2024

(30) Foreign Application Priority Data
May 29, 2024 (KR) 10-2024-0070348

(51) Int. Cl. H02J 7/00; B60L 53/14; B60L 53/30; B60L 53/66

(52) U.S. Cl. CPC H02J 7/0042; H02J 7/00032; B60L 53/14; B60L 53/305; B60L 53/665

(57) ABSTRACT

A charger is provided. The charger comprises a main body, a front body having an outer surface and a front surface and coupled to the main body, a body deco cover configured to cover the outer surface, and a front deco configured to cover the front surface. The charger may have a dual structure of the front body and the front deco in a front and rear direction and a dual structure of the front body and the body deco cover in a left and right direction to minimize damage of components accommodated between the front body and the main body by external fire, flooding, or external force.

### CROSS-REFERENCE TO RELATED APPLICATION(S)

Pursuant to 35 U.S.C. § 119 (a), this application claims the benefit of earlier filing date and right of priority to Korean Patent Application No. 10-2024-0070348, filed on May 29, 2024, the contents of which are all hereby incorporated by reference herein in their entireties.

### BACKGROUND

The present disclosure relates to a charger.

A charger is a device used to charge storage batteries.

An example of the charger may be an electric vehicle charger that charges vehicles such as electric vehicles. Here, a connector provided on an end of a charging cable is connected to a connection inlet installed on the electric vehicle to supply electrical energy to a battery of the electric vehicle.

To use the charging cable, the charger may be used by unwinding and pulling out the wound charging cable and then inserting a charging connector into an inlet of the electric vehicle.

An electric vehicle charger in which an internal multi-stage structure including a charging cable is provided is disclosed in Korea Patent Publication No. 10-2626989 B1 (announced on Jan. 19, 2024). The electric vehicle charger having the internal multi-stage structure may comprise a charging cable, a main body unit having an internal space, in which the components are disposed, and supplying power to the charging cable, and a front door unit that is opened and closed from the main body unit, the components inside the main body unit may be divided into a first unit, a second unit, and a third unit, the main body unit may comprise a control module that controls an operation of the main body unit or the front door unit, and a power module that converts the supplied power into charging power for the charging the electric vehicle, the power module may be provided in the second unit, and the control module may be provided in the third unit.

### SUMMARY

A charger according to the related art has a limitation in that internal components are easily damaged by rainwater or dust.

In one embodiment, a charger comprises: a main body; a front body having an outer surface and a front surface and coupled to the main body; a body deco cover configured to cover the outer surface; and a front deco configured to cover the front surface.

The charger may further comprise a wall mounter coupled to a rear surface of the main body.

The charger may further comprise a sealing ring configured to seal a gap between the main body and the front body.

The charger may further comprise an AC board accommodated in a space between the main body and the front body.

The charger may further comprise a modem accommodated in a space between the main body and the front body.

The charger may further comprise a metering board accommodated in a space between the main body and the front body.

The charger may further comprise a control board accommodated in a space between the main body and the front body.

The charger may further comprise a speaker accommodated in a space between the main body and the front body. A speaker hole may be defined in the front deco.

The charger may further comprise a payment reader accommodated in a space between the main body and the front body.

The charger may further comprise a Wi-Fi module accommodated in a space between the main body and the front body.

The charger may further comprise an LED diffusion plate disposed between the front body and the front deco. A light transmission window through which light diffused from the LED diffusion plate may be transmitted is provided on the front deco.

The charger may further comprise a display disposed between the front body and the front deco. A window through which light generated from the display is transmitted may be disposed on the front deco.

The charger may further comprise a cable holder which is disposed on the front body and on which a charging cable is mounted.

The cable holder may comprise: a holder with a top surface and both side surfaces opened; and an inner cover disposed inside the holder,

A through-hole through which the charging cable passes may be defined in the front deco and the front body.

The charger may further comprise a Bluetooth pairing key disposed between the front body and the front deco. A pin insertion hole into which a pin configured to manipulate the Bluetooth pairing key is inserted may be defined in the front deco.

The outer surface may have an inner reduction area that is gradually reduced from a rear end to a front end thereof.

The body deco cover may have an outer reduction area that is gradually reduced from a rear end to a front end thereof to correspond to the inner reduction area.

The front body may be an inner case concealed by the body deco cover.

The body deco cover may be an outer case exposed to the outside of the front body and coupled to the front body.

A gap may be defined between an inner surface of the body deco cover and the outer surface.

A groove may be defined in one of the front body and the body deco cover.

A protrusion inserted into the groove may be disposed on the other of the front body and the body deco cover.

A coupling portion in which the groove is recessed may protrude from the outer surface.

The details of one or more embodiments are set forth in the accompanying drawings and the description below. Other features will be apparent from the description and drawings, and from the claims.

### BRIEF DESCRIPTION OF THE DRAWINGS

FIG. 1 is a front view of a charger according to an embodiment.

FIG. 2 is a cross-sectional view illustrating the inside of the charger according to an embodiment.

FIG. 3 is an exploded perspective view of the charger according to an embodiment.

FIG. 4 is a control block diagram of the charger according to an embodiment.

FIG. 5 is a rear view of a front deco according to an embodiment.

FIG. 6 is a rear view of a front body according to an embodiment.

FIG. 7 is a front view of a main body according to an embodiment.

FIG. 8 is a cross-sectional view taken along line A-A of FIG. 1.

FIG. 9 is a cutaway perspective view illustrating a portion of a line B-B of FIG. 1.

FIG. 10 is a cross-sectional view when a charging cable is mounted on a cable holder according to an embodiment.

### DETAILED DESCRIPTION OF THE EMBODIMENTS

Hereinafter, specific embodiments of the present invention will be described in detail with drawings.

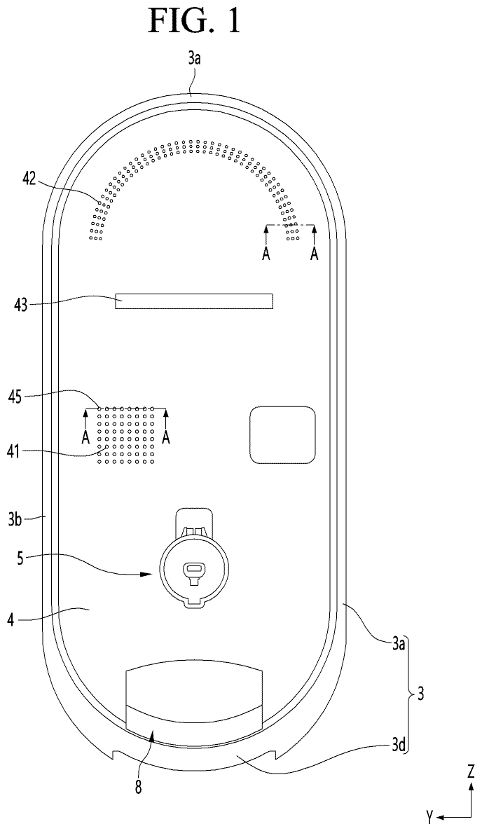

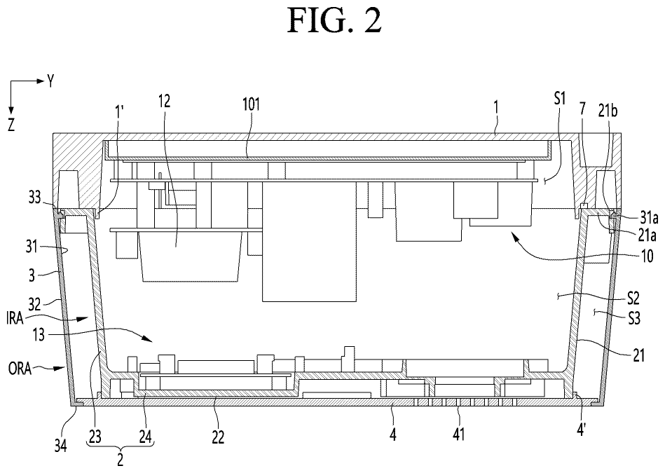

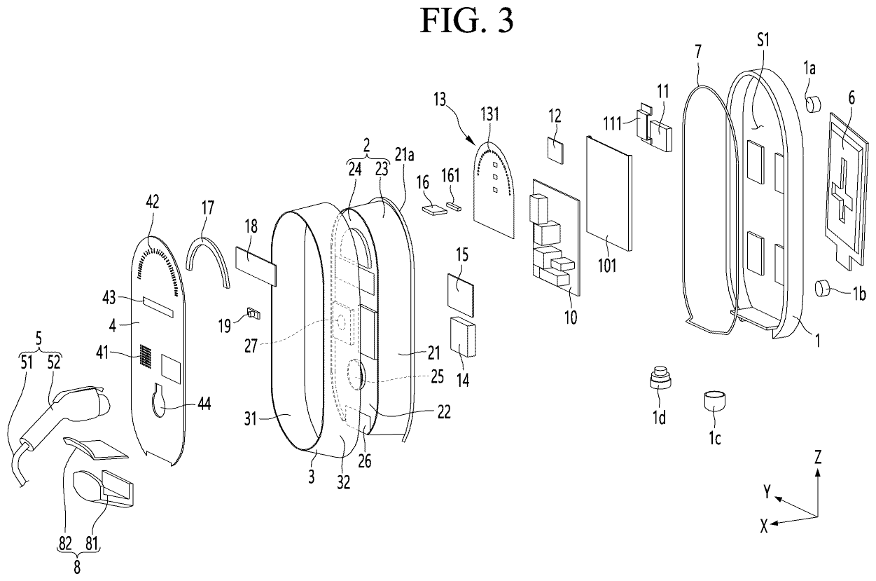

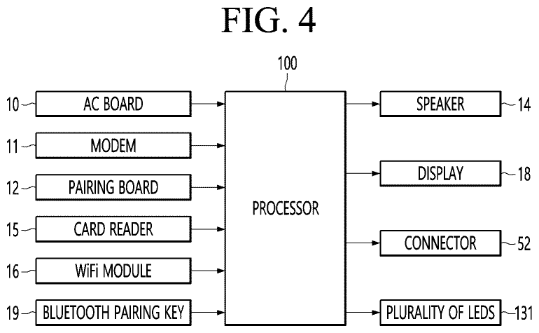

FIG. 1 is a front view of a charger according to an embodiment, FIG. 2 is a cross-sectional view illustrating the inside of the charger according to an embodiment, FIG. 3 is an exploded perspective view of the charger according to an embodiment, and FIG. 4 is a control block diagram of the charger according to an embodiment.

A charger may comprise a main body 1, a front body 2, a body deco cover 3, and a front deco 4. The charger may comprise a charging cable 5 that charges a vehicle such as an electric vehicle.

The charging cable 5 may comprise a cable body 51, a connection body (not shown) disposed on one end of the cable body 51 and connected to a power supply, and a connector 52 (or charging gun) disposed on the other end of the cable body 51 and connected to or disconnected from the vehicle such as the electric vehicle.

A power line may be accommodated inside the cable body 51 and may be provided to be bendable.

The main body 1 may have a box shape with a front surface opened.

A rear space S1 may be defined inside the main body 1.

At least one electrical component may be accommodated in the rear space S1.

An example of the main body 1 may be made of a PC material.

A front rib 1′ that is in contact with the front body 2 may protrude forward from the main body 1.

The front rib 1′ may be inserted into the front space S2 of the front body 2.

The charger may be a wall-mounted charger and may further comprise a wall mounter 6. The wall mounter 6 may be coupled to a rear surface of the main body 1.

The main body 1 may be coupled to the wall mounter 6 using a coupling member such as a hook or screw.

A size of the wall mounter 6 may be less than that of the main body 1 and may be concealed by the main body 1 when viewed from the front.

The wall mounter 6 may be made of a metal material. The wall mounter 6 may be installed on a wall of a charging station. The wall mounter 6 may be coupled to the wall using a coupling member such as a bolt.

When the main body 1 is coupled to the wall mounter 6, and the wall mounter 6 is coupled to the wall, the main body 1 may be spaced apart from the ground in a vertical direction Z.

The main body 1 may be provided in a dual structure by the wall mounter 6 in a rear surface of the charger.

The front body 2 may be coupled to the main body 1. The front body 2 may be disposed on the a front surface of the main body 1.

The front body 2 may have an opened rear surface. A front space S2 (see FIG. FIG. 2) may be defined inside the front body 2.

The front body 2 may have an outer surface 21 and a front surface 22.

The front body 2 may comprise an outer portion 23 having the outer surface 21 defined thereon, and a front surface portion 24 disposed on the outer portion 23 and having the front surface 22 defined thereon.

The outer portion 23 may comprise the outer surface 21 and an inner surface disposed at an opposite side of the outer surface 21 and facing the front space S2.

The outer surface 21 may comprise an inner reduction area IRA.

As illustrated in FIG. 2, the inner reduction area IRA may be an area that is gradually reduced from a rear end to a front end thereof.

The inner reduction area IRA may be defined on an entire area of the outer surface 21 or may be provided as a partial area of the outer surface 21.

The front surface portion 24 may comprise a front surface 22 and a rear surface disposed at an opposite side of the front surface 22 and facing the front space S2.

The outer portion 23 of the front body 2 may be provided to be elongated in the vertical direction Z. The outer portion 23 of the front body 2 may comprise a left body, a right body spaced apart from the left body in a left and right direction, an upper body connecting an upper end of the left body to an upper end of the right body, and a lower body connecting a lower end of the left body to a lower end of the right body.

The front body 2 may be accommodated in an inner space S3 defined by the main body 1, the body decor cover 3, and the front decor 4 and may be protected by the main body 1, the body decor cover 3, and the front deco 4. The front body 2 may be an inner housing disposed inside the charger.

A cable through-hole 25 through which the charging cable 5 passes may be defined in the front body 2. The cable through-hole 25 may be opened in a front and rear direction X.

A cable holder coupling portion 26 to which the cable holder 8 is coupled may be disposed at a lower portion of the front body 2.

The cable holder coupling portion 26 may be disposed at a lower portion of the front surface portion 24 of the front body 2.

A speaker hole 27 may be defined in the front body 2. The speaker hole 27 may be spaced apart from the cable through-hole 25 and the cable holder coupling portion 26.

An example of the front body 2 may be made of a PC material.

The front body 2 may be an inner case concealed by the body deco cover 3.

The charger may further comprise a sealing ring 7.

The sealing ring 7 may be disposed between the main body 1 and the front body 2 to seal a gap between the main body 1 and the front body 2.

The sealing ring 7 may be inserted into and accommodated in a groove defined in the front surface of the main body 1 and may be in contact with a rear end of the front body 2. The sealing ring 7 may prevent rainwater or dust from being penetrated into a space defined between the main body 1 and the front body 2.

An example of the sealing ring 7 may be made of rubber.

The body deco cover 3 may cover the outer surface 21 at the outside of the front body 2.

The body deco cover 3 may be provided to be elongated in the vertical direction Z. As illustrated in FIG. 1, the body deco cover 3 may comprise a left cover 3a, a right cover 3b spaced apart from the left cover 3a in the left and right direction, an upper cover 3c connecting an upper end of the left cover 3a to an upper end of the right cover 3b, and a lower cover 3b connecting a lower end of the left cover 3a to a lower end of the right cover 3b.

Each of the left cover 3a and the right cover 3b may be provided to be elongated in the vertical direction.

The upper cover 3c may be provided in a curved shape that is convex upward.

The upper cover 3c may be provided to be inclined downward as it moves forward.

The lower cover 3d may be provided in a curved shape that is convex downward.

The lower cover 3c may be provided to be inclined upward as it moves forward.

The body deco cover 3 may be coupled to at least one of the main body 1 or the front body 2.

A rear end 33 of the body deco cover 3 may be coupled to the main body 1.

A front end of the body deco cover 3 may be coupled to the front deco 4.

The body deco cover 3 may surround the front body 2 between the main body 1 and the front deco 4.

The body decor cover 3 may comprise an inner surface 31 and an outer surface 32.

The body deco cover 3 may be an outer case exposed from the outside of the front body 2 and may constitute a dual case together with the front body 2.

A gap G may be defined between the inner surface 31 of the body decor cover 3 and the outer surface 22 of the front body 2, and air may be accommodated in the gap G.

The air between the inner surface 31 of the body decor cover 3 and the outer surface 22 of the front body 2 may function as an insulating material.

The body deco cover 3 may comprise an outer reduction area ORA.

As illustrated in FIG. 2, the outer reduction area ORA may be gradually reduced from a rear end to a front end thereof and may be an area corresponding to the inner reduction area IRA.

The outer reduction area ORA may be an entire area or a partial area of the body decor cover 3.

The body deco cover 3 may be a side deco that defines an outer appearance of the outer surface of the charger.

An example of the body decor cover 3 may be made of a PC material.

A side surface of the charger may be provided in a dual structure by the body deco cover 3 and the front body 2.

The body deco cover 3 may be coupled to the front body 2.

A coupling portion 21a coupled to the body decor cover 3 may be provided on the outer surface 21 of the front body 2.

The coupling portion 21a may protrude from the outer surface 21 of the front body 2.

A groove 21b may be defined in one of the front body 2 and the body deco cover 3, and a protrusion 31a inserted into and coupled to the groove 21b may be disposed on the other of the front body 2 and the body deco cover 3.

When the groove 21b is defined in the coupling portion 21a, the protrusion 31a may be disposed on an inner outer surface 31 of the body decor cover 3.

When the groove 21b is defined in the inner outer surface 31 of the body decor cover 3, the protrusion 31a may be disposed on the coupling portion 21a.

The rear end 33 of the body deco cover 3 may be in contact with a front edge of the main body 1.

A stopper 34 on which an edge of the front deco 4 is hung may be disposed on a front end of the body deco cover 3.

The front deco 4 may cover the front surface 22 of the front body 2 at the front side of the front body 2.

The front deco 4 may be an outer deco that defines an outer appearance of the front surface of the charger.

The front surface of the charger may be provided in a dual structure by the front deco 4 and the front body 2.

A rear rib 4′ that is in contact with the front body 2 may protrude backward from the rear surface of the front deco 4. The front end of the front body 2 may be inserted into the rear rib 4′.

The front deco 4 may be restricted in the left and right direction by the rear rib 4′.

The front deco 4 may be restricted forward by the stopper 34 and restricted backward by the front body 2.

An example of the front deco 4 may be made of a PC material.

A speaker hole 41 may be defined in the front deco 4.

The speaker hole 41 may be provided in plurality. The plurality of speaker holes 41 may be spaced apart from each other in the vertical direction Z and the left and right direction Y.

A plurality of rows of speaker holes 41 may be defined in the front deco 4.

A light transmission window 42 may be disposed in the front deco 4.

The light transmission window 42 may be inserted into the front deco 4, or an opening hole may be defined in front of the light transmission window 42. The opening hole may be provided in plurality.

A window 43 may be disposed on the front deco 4.

An input unit such as a touch screen may be disposed on the window 43.

A cable through-hole 44 may be defined in the front deco 4. The cable through-hole 44 may be opened in a front and rear direction X.

When the connector 52 of the cable 5 is not used, the connector 52 may be sequentially inserted into the cable through-hole 44 of the front deco 4 and the cable through-hole 25 of the front body 2 and also may be mounted on at least one of the front deco 4 or the front body 2.

The charger may further comprise a cable holder 8 which is disposed on the front body 2 and on which the charging cable 6 is mounted.

The cable holder 8 may comprise a holder 81, of which top and both side surfaces are opened, and an inner cover 82 disposed inside the holder 81.

A rear surface of the holder 81 may be coupled to the cable holder coupling portion 26 of the front body 2 using a coupling member such as a screw.

The charger may comprise a power supply.

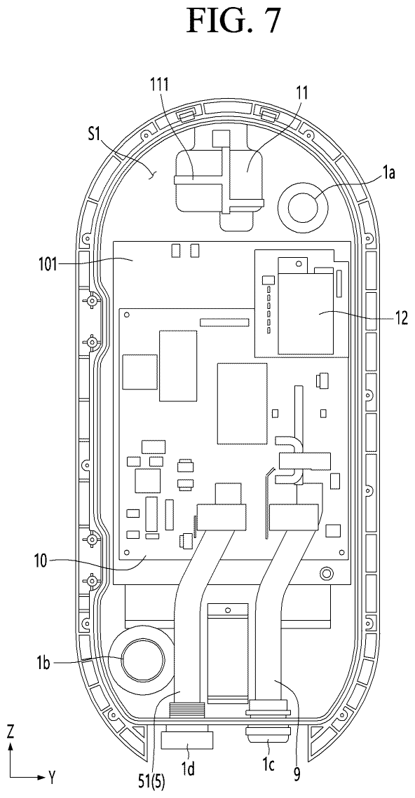

A power cable 9 (see FIG. 7) may be connected to the power supply.

The connection body of the charging cable 5 may be connected to the power supply, and the power supply may supply power to the charging cable 5.

The power supply may convert alternating current applied from the outside through the power cable into direct current to supply the direct current to the charging cable 5.

The charger may be a slow charger.

An example of the power supply may comprise an AC board 10 that converts alternating current to direct current.

The AC board 10 may be accommodated in a space between the main body 1 and the front body 2, a space between the front body 2 and the body deco cover 3, and a space between the front body 2 and the front deco 4.

The AC board 10 may be accommodated in the space between the main body 1 and the front body 2 for waterproofing and dustproofing.

The AC board 10 may be mounted on the main body 1 or the front body 2.

The AC board 10 may be an analog board on which semiconductors or diodes are installed.

A supporter 101 for mounting of the AC board 10 may be disposed in the rear space S1 of the main body 1.

The charger may comprise at least one communication module.

The charger may further comprise a modem 11 capable of communicating with the outside of the charger.

The modem 11 may be accommodated in a space between the main body 1 and the front body 2, a space between the front body 2 and the body deco cover 3, and a space between the front body 2 and the front deco 4.

The modem 11 may be accommodated in the space between the main body 1 and the front body 2 for waterproofing and dustproofing.

The modem 11 may be mounted on the main body 1 or the front body 2.

A modem guide 111 for mounting of the modem 11 may be disposed in the rear space S1 of the main body 1.

The charger may further comprise a metering board 12 that is capable of measuring an amount of power that is being charged when charging the electric vehicle.

The metering board 12 may be accommodated in a space between the main body 1 and the front body 2, a space between the front body 2 and the body deco cover 3, and a space between the front body 2 and the front deco 4.

The metering board 12 may be accommodated in the space between the main body 1 and the front body 2 for waterproofing and dustproofing.

The metering board 12 may be mounted on the main body 1 or the front body 2.

The charger may further comprise a control board 13.

The control board 13 may comprise a processor 100 that controls an overall operation of the charger.

The control board 13 may be accommodated in a space between the main body 1 and the front body 2, a space between the front body 2 and the body deco cover 3, and a space between the front body 2 and the front deco 4.

The control board 13 may be accommodated in the space between the main body 1 and the front body 2 for waterproofing and dustproofing.

The control board 13 may be mounted on the main body 1 or on the front body 2.

The control board 13 may be mounted on the front body 2.

The control board 13 may be a digital board.

LEDs 131 may be arranged on the front surface of the control board 13. The LEDs 131 may be provided in plurality, and the plurality of LEDs 131 may be arranged in a shape corresponding to an LED diffusion plate 17. The plurality of LEDs 131 may be arranged to be spaced apart from each other along an arc-shaped trajectory.

Light generated from the LEDs 131 may pass through the front body 2 and then be diffused while passing through the LED diffusion plate 17 and may be emitted to the outside through the light transmission window 42.

The charger may further comprise a speaker 14.

The speaker 14 may be accommodated in a space between the main body 1 and the front body 2, a space between the front body 2 and the body deco cover 3, and a space between the front body 2 and the front deco 4.

The speaker 14 may be accommodated in the space between the main body 1 and the front body 2 for waterproofing and dustproofing.

The speaker 14 may be mounted on the main body 1 or the front body 2.

The speaker 14 may be mounted on the front body 2. The control board 13 may be disposed on a rear surface of the front surface portion 24 of the front body 2. The control board 13 may be disposed behind the speaker hole 27 of the front body 2.

The speaker 14 may be coupled to the front surface portion 24 of the front body 2 using a coupling member such as a screw.

Sound or voice messages generated from the speaker 14 may pass through the speaker hole 27 defined in the front body 2. The Sound or voice messages generated from the speaker 14 may pass through the speaker hole 41 defined in the front deco 4.

The charger may further comprise a payment reader 15.

An example of the payment reader 15 may be a card reader.

A manager may manage the charger by accessing the manager card to the payment reader 15.

A user of the vehicle such as the electric vehicle may access the payment card to the payment reader 15 to pay charging costs.

The payment reader 15 may be accommodated in a space between the main body 1 and the front body 2, a space between the front body 2 and the body deco cover 3, and a space between the front body 2 and the front deco 4.

The payment reader 15 may be accommodated in the space between the main body 1 and the front body 2 for waterproofing and dustproofing.

The payment reader 15 may be mounted on the main body 1 or the front body 2.

The payment reader 15 may be mounted on the front body 2.

The charger may further comprise a Wi-Fi module 16.

The WiFi module 16 may be accommodated in a space between the main body 1 and the front body 2, a space between the front body 2 and the body deco cover 3, and a space between the front body 2 and the front deco 4.

The Wi-Fi module 16 may be accommodated in the space between the main body 1 and the front body 2 for waterproofing and dustproofing.

The Wi-Fi module 16 may be mounted on the main body 1 or the front body 2.

The Wi-Fi module 16 may be mounted on the front body 2. The Wi-Fi module 16 may be mounted on the front surface portion 24 of the front body 2 to be disposed at an upper side of the control board 13.

A Wi-Fi guide 161 for mounting of the Wi-Fi module 16 may be disposed in the rear space S2 of the front body 2.

The Wi-Fi guide 161 may be disposed on a rear surface of the front surface portion 24 of the front body 2.

The charger may further comprise the LED diffusion plate 17.

The LED diffusion plate 17 may be disposed between the control board 13 and the light transmission window 42 in the front and rear direction X.

The LED diffusion plate 17 may be disposed between the front body 2 and the front deco 4.

The LED diffusion plate 17 may diffuse the light generated by the LEDs 131 and minimize concentration of some of the light generated by the plurality of LEDs 131 to a portion of the light transmission window 42.

The light transmission window 42 through which the light diffused from the LED diffusion plate 17 is transmitted may be disposed in the front deco 4.

The charger may further comprise a display 18 that displays various information such as charging information or payment information.

The display 18 may be disposed between the front body 2 and the front deco 4.

The display 18 may be disposed on a front surface of the front surface portion 24 of the front body 2. The display 18 may be coupled to the front surface of the front surface portion 24 of the front body 2 using a coupling member such as a screw.

An example of the display 18 may be an LED panel.

A window 43 through which the light generated from the display 18 is transmitted may be disposed on the front deco 4. The window 43 may be provided to be elongated in the left and right direction Y.

The display 18 may display various information about the charger through the window 43 at the rear side of the window 43.

The charger may further comprise a Bluetooth pairing key 19.

The manager or service provider may reset Bluetooth by manipulating the Bluetooth pairing key 19, and the charger may be Bluetooth-paired with peripheral devices.

The Bluetooth pairing key 19 may be disposed between the front body 2 and the front deco 4.

A pin insertion hole 45 may be defined in the front deco 4 through which a pin (not shown) for manipulating the Bluetooth pairing key 19 passes.

The pin insertion hole 45 may be defined close to the speaker hole 41.

A size of the pin insertion hole 45 may be the same as the size of the speaker hole 41.

The pin insertion hole 45 may also be used in common with one of the speaker holes 41.

It is desirable for general users (e.g., consumers) to be unable to distinguish the pin insertion hole 45 from the speaker hole 41 when viewing the front deco 4 from the outside, and the pin insertion hole 45 may be provided in the same shape or size as the speaker hole 41 in an area in which the plurality of speaker holes 41 are defined.

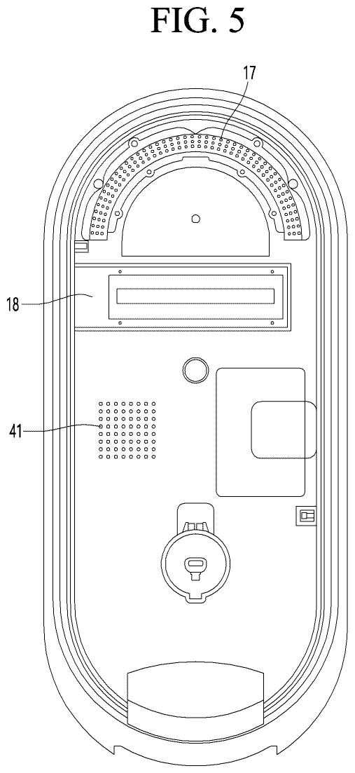

FIG. 5 is a rear view of the front deco according to an embodiment.

The LED diffusion plate 17 may be disposed on a rear surface of the front deco 4.

The LED diffusion plate 17 may have an arc shape that is convex upward.

The display 18 may display various information about the charger through the window 43 at the rear side of the front deco 4.

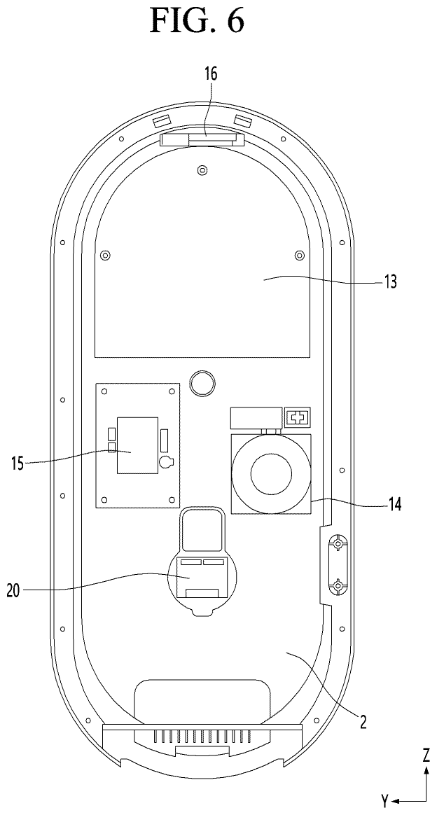

FIG. 6 is a rear view of the front body according to an embodiment.

The control board 13 may be disposed on a rear surface of the front surface portion 24 of the front body 2. The control board 13 may be coupled to the front body 2 with a coupling member such as a screw.

An upper portion of the control board 13 may be provided in a semicircular shape.

The speaker 14 may be disposed on a rear surface of the front surface portion 24 of the front body 2.

The speaker 14 may be spaced apart from the control board 13 in the vertical direction Z.

The payment reader 15 may be disposed on the rear surface of the front surface portion 24 of the front body 2 so as to be spaced apart from the speaker 14 in the left and right direction Y.

The payment reader 15 may be spaced apart from the control board 13 in the vertical direction Z.

The Wi-Fi guide 161 may be disposed on a rear surface of the front surface portion 24 of the front body 2. The Wi-Fi module 16 may be disposed on the rear surface of the front surface portion 24 of the front body 2.

A side end of each of the control board 13, the speaker 14, the payment reader 15, and the Wi-Fi module 16 may be doubly protected by the front body 2 and body deco cover 3.

A front surface of each of the control board 13, the speaker 14, the payment reader 15, and the Wi-Fi module 16 may be doubly protected by the front body 2 and front deco 4.

The charger may further comprise a connector sensor 20 (e.g., gun sensor) capable of sensing installation of the connector 52.

The connector sensor 20 may be a sensor capable of sensing proximity of the connector 52.

The connector sensor 20 may be provided as a proximity sensor or an optical sensor and may not be limited to its type as long as it may sense the connector 52.

The connector sensor 20 may be disposed inside the front body 2 to sense the cable 5, especially the connector 52, when the cable 5, especially the connector 52, passes through the cable through-hole 25.

FIG. 7 is a front view of the main body according to an embodiment.

The supporter 101 may be coupled to the main body 1 using a coupling member such as a screw.

A size of the supporter 101 may be greater than that of the AC board 10 and may protect the AC board 10 at a rear side of the AC board 10.

A rear surface of the AC board 10 may be doubly protected by the supporter 101 and the main body 1.

The metering board 12 may be installed on the front surface of the supporter 101 or the AC board 10.

The modem guide 111 may be coupled to the main body 1 with a coupling member such as a screw.

The modem 11 may be supported on the modem guide 111.

The modem 11 may be spaced apart from the AC board 10 in the vertical direction Z.

A LAN cable cover 1a through which a LAN cable passes may be disposed on the main body 1.

The LAN cable cover 1a may be disposed at an upper portion of a rear plate of the main body 1.

The LAN cable may be disposed to pass through the main body 1 and connected to the modem 11.

A power cable cover 1b that blocks the cable through-hole, through which the power cable 9 passes, may be disposed on the main body 1.

The power cable cover 1b may be disposed at a lower portion of the rear plate of the main body 1.

A power cable connector 1c through which the power cable 9 passes may be disposed on the main body 1.

The power cable connector 1c may be disposed on the lower plate of the main body 1.

The installer may pass the power cable through one of the power cable cover 1b disposed at a lower portion of the rear plate of the main body 1 and the power cable connector 1c disposed on the lower plate of the main body 1 to connect the power cable 9 to the AC board 10.

A charging cable connector 1d through which the cable body 51 passes may be disposed on the main body 1.

The charging cable connector 1d may be disposed on the lower plate of the main body 1. The charging cable connector 1d may be spaced apart from the power cable connector 1c in the left and right direction.

An installer may allow the charging cable 5 to pass through the charging cable connector 1d and connect the charging cable 5 to the AC board 10.

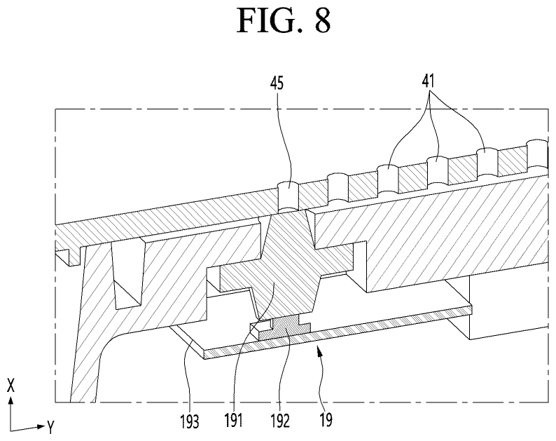

FIG. 8 is a cross-sectional view taken along line A-A of FIG. 1.

The Bluetooth pairing key 19 may comprise a key 191 pressed by a pin, a switch 192 switched by the key 191, and a PCB 193 on which the switch 192 is installed.

The key 191 may be disposed behind the pin insertion hole 45. The key 191 may be disposed between the front deco 4 and the switch 192.

An example of the switch 192 may be a tact switch.

The manager or service provider may insert the pin into the pin insertion hole 45 from a front side of the pin insertion hole 45 of the front deco 4, and the pin inserted into the pin insertion hole 45 may press the key 191.

When the key 191 is pressed, the switch 192 may be switched, a Bluetooth function may be reset, and the charger may be Bluetooth-paired with the peripheral devices.

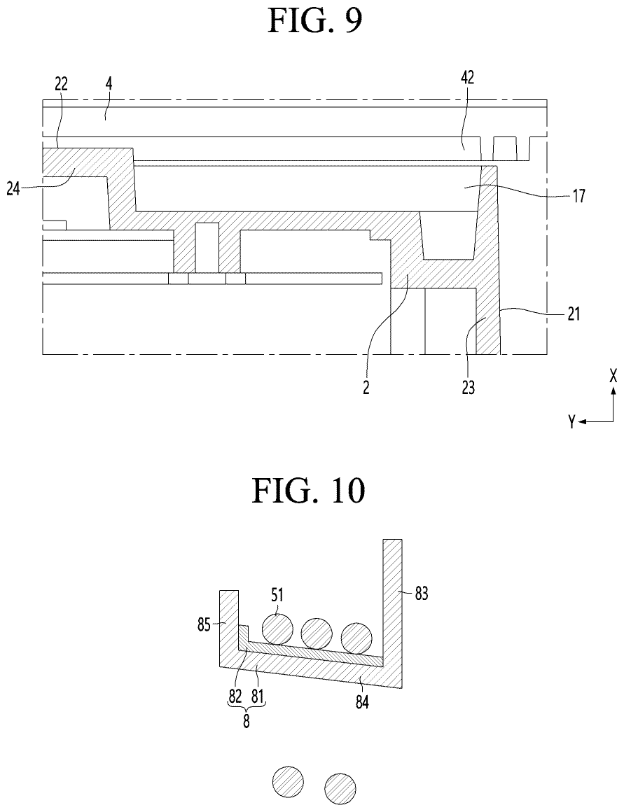

FIG. 9 is a cutaway perspective view illustrating a portion of a line B-B of FIG. 1.

The light transmission window 42 may be made of a PC material and may be provided to be semi-transparent.

The LED diffusion plate 17 may be disposed behind the light transmission window 42 and may diffuse the light so that the light is not concentrated to a specific area.

The light diffused from the LED diffusion plate 17 may be emitted to the outside through the semi-transparent light transmission window 42.

FIG. 10 is a cross-sectional view when the charging cable is mounted on the cable holder according to an embodiment.

The holder 81 may comprise a rear holder 83 coupled to the cable holder coupling portion 26, a lower holder extending forward or forward and upward from the rear holder 83, and a front holder 85 extending upward from the lower holder 84.

The front holder 85 may function as a stopper to prevent the cable body 51 from being slid forward.

The front holder 85 may be provided at a height that facilitates the mounting of the cable body 51, and a height of the front holder 85 may be lower than that of the rear holder.

An inner cover 82 may be disposed between the rear holder 83 and the front holder 85. The inner cover 82 may be seated on a top surface of the lower holder 84.

When the cable 5 is not used, the cable body 51 may be wound around the cable holder 8 at least once.

If the inner cover 82 is not provided, the cable body 51 may be placed on the lower holder 84. In this case, frequent friction between the cable body 51 and the lower holder 84 may occur, and the number of replacements of the holder 81 may increase.

The inner cover 82 may be detachably coupled to the holder 81 and may be in contact with the cable body 51 when the cable body 51 is seated.

When the cable body 51 is frequently seated, the inner cover 82 may be damaged by the cable 5, and the service provider may replace only the inner cover 82 with a new inner cover while maintaining the holder 81 on the front body 2.

According to this embodiment, the charger may have the dual structure of the front body and the front deco in the front and rear direction and the dual structure of the front body and the body deco cover in the left and right direction to minimize the damage of the components accommodated between the front body and the main body by external fire, flooding, or external force.

In addition, even if the gap is generated between the front deco and the body deco cover or between the body deco cover and the main body due to the external impact, etc., the inside of the main body may be waterproof/dustproof, and the charger may be used continuously.

In addition, it has the dual structure of the main body and the wall mounter, and thus, the components accommodated between the front body and the main body may be doubly protected.

In addition, there may be the gap in which air exists between the front body and the body deco cover or between the front body and the front deco, and thus, the occurrence of the condensation due to the temperature difference between the inside and the outside of the charger may be minimized due to a thermal insulation effect.

In addition, the electrical components such as the AC board and the control board may be accommodated between the front body and the main body to minimize malfunction due to the external fire or flooding.

In addition, the electrical components such as the display or the Bluetooth repairing key may be accommodated between the front deco and the front body to improve convenience.

In addition, an occurrence of hot spots in the light transmission window may be minimized by the LED diffusion plate.

In addition, the Bluetooth pairing key may be concealed by the front deco to upgrade the front surface of the charger, minimize possibility of the user's malfunction of the Bluetooth pairing key, and thus, the manager may conveniently manipulate the Bluetooth pairing key through the pin insertion hole.

The above-disclosed subject matter is to be considered illustrative, and not restrictive, and the appended claims are intended to cover all such modifications, enhancements, and other embodiments, which fall within the true spirit and scope of the present disclosure.

Thus, the embodiment of the present disclosure is to be considered illustrative, and not restrictive, and the technical spirit of the present disclosure is not limited to the foregoing embodiment.

Therefore, the scope of the present disclosure is defined not by the detailed description of the invention but by the appended claims, and all differences within the scope will be construed as being comprised in the present disclosure.

What is claimed is:

1. A charger comprising:
a main body;
a front body having an outer surface and a front surface and coupled to the main body;
a body deco cover configured to cover the outer surface; and
a front deco configured to cover the front surface.

2. The charger according to claim 1, further comprising a wall mounter coupled to a rear surface of the main body.

3. The charger according to claim 1, further comprising a sealing ring configured to seal a gap between the main body and the front body.

4. The charger according to claim 1, further comprising an AC board accommodated in a space between the main body and the front body.

5. The charger according to claim 1, further comprising a modem accommodated in a space between the main body and the front body.

6. The charger according to claim 1, further comprising a metering board accommodated in a space between the main body and the front body.

7. The charger according to claim 1, further comprising a control board accommodated in a space between the main body and the front body.

8. The charger according to claim 1, further comprising a speaker accommodated in a space between the main body and the front body,
wherein a speaker hole is defined in the front deco.

9. The charger according to claim 1, further comprising a payment reader accommodated in a space between the main body and the front body.

10. The charger according to claim 1, further comprising a Wi-Fi module accommodated in a space between the main body and the front body.

11. The charger according to claim 1, further comprising an LED diffusion plate disposed between the front body and the front deco,
wherein a light transmission window through which light diffused from the LED diffusion plate is transmitted is provided on the front deco.

12. The charger according to claim 1, further comprising a display disposed between the front body and the front deco,
wherein a window through which light generated from the display is transmitted is disposed on the front deco.

13. The charger according to claim 1, further comprising a cable holder which is disposed on the front body and on which a charging cable is mounted.

14. The charger according to claim 13, wherein the cable holder comprises:
a holder with a top surface and both side surfaces opened; and
an inner cover disposed inside the holder,
wherein a through-hole through which the charging cable passes is defined in the front deco and the front body.

15. The charger according to claim 1, further comprising a Bluetooth pairing key disposed between the front body and the front deco,
wherein a pin insertion hole into which a pin configured to manipulate the Bluetooth pairing key is inserted is defined in the front deco.

16. The charger according to claim 1, wherein the outer surface has an inner reduction area that is gradually reduced from a rear end to a front end thereof.

17. The charger according to claim 16, wherein the body deco cover has an outer reduction area that is gradually reduced from a rear end to a front end thereof to correspond to the inner reduction area.

18. The charger according to claim 1, wherein the front body is an inner case concealed by the body deco cover,
the body deco cover is an outer case exposed to the outside of the front body and coupled to the front body, and
a gap is defined between an inner surface of the body deco cover and the outer surface.

19. The charger according to claim 1, wherein a groove is defined in one of the front body and the body deco cover, and
a protrusion inserted into the groove is disposed on the other of the front body and the body deco cover.

20. The charger according to claim 19, wherein a coupling portion in which the groove is recessed protrudes from the outer surface.
